(19) United States
(12) Patent Application Publication
(10) Pub. No.: US 2025/0179630 A1
(43) Pub. Date: Jun. 5, 2025

(54) Substrate Treatment Device, Fluid Activation Device, Substrate Treatment Method, and Fluid Activation Method

(71) Applicants: Tokyo Electron Limited, Tokyo (JP); National Institute of Advanced Industrial Science and Technology, Tokyo (JP)

(72) Inventors: Yusuke KUBOTA, Tokyo (JP); Hachishiro IIZUKA, Yamanshi (JP); Shigenori OZAKI, Yamanashi (JP); Jun YAMAWAKU, Yamanashi (JP); Takahiro SHINDO, Tokyo (JP); Yoshiki YAMANISHI, Osaka (JP); Masaki NARUSHIMA, Yamanashi (JP); Masateru NISHIOKA, Miyagi (JP)

(21) Appl. No.: 19/044,154

(22) Filed: Feb. 3, 2025

Related U.S. Application Data
(63) Continuation of application No. PCT/JP2023/027038, filed on Jul. 24, 2023.

(30) Foreign Application Priority Data
Aug. 3, 2022 (JP) 2022-123673

(51) Int. Cl. C23C 16/452; C23C 16/511

(52) U.S. Cl. CPC C23C 16/452; C23C 16/511

(57) ABSTRACT

A substrate processing apparatus comprises a processing chamber configured to accommodate a substrate, a stage disposed in the processing chamber and on which the substrate is placed, a fluid supply source configured to supply processing fluid to the processing chamber, a plurality of cylindrical metallic resonators having a bottom portion and a lid, which are disposed in the processing chamber, a tube body made of a dielectric material, which extends along a central axis of each resonator, penetrates the resonator, and forms a fluid channel through which the processing fluid is supplied. A plurality of discharge holes is provided in the processing chamber, each opening toward different positions of the substrate and connected to different fluid channels. A plurality of microwave supply sources is provided to supply microwaves to different resonators and activate the processing fluid within an activation region surrounded by the resonator in each fluid channel.

### CROSS-REFERENCE TO RELATED APPLICATIONS

This application is a bypass continuation application of International Application No. PCT/JP2023/027038 having an international filing date of Jul. 24, 2023 and designating the United States, the International Application being based upon and claiming the benefit of priority from Japanese Patent Application No. 2022-123673 filed on Aug. 3, 2022, the entire contents of which are incorporated herein by reference.

### TECHNICAL FIELD

The present disclosure relates to a substrate processing apparatus, a fluid activation apparatus, a substrate processing method, and a fluid activation method.

### BACKGROUND

In a semiconductor device manufacturing process, a semiconductor wafer (hereinafter, referred to as “wafer”) as a substrate is accommodated in a processing chamber constituting a substrate processing apparatus, and a processing gas is supplied to perform processing such as film formation or etching. On the other hand, Japanese Patent No. 4759668 shows a heating apparatus using microwaves. The heating apparatus includes a metallic cavity resonator having a cylindrical sidewall and end sidewalls (end walls) provided at both axial ends of the sidewall. A circular tube is provided coaxially with the cavity resonator. Further, a microwave waveguide is connected to an intermediate position in an axial direction of the cylindrical sidewall, and fluid in a reaction tube is heated by the supply of microwaves.

### SUMMARY

The present disclosure provides a technique capable of avoiding scaling up of a device configuration in the case of supplying fluid to a processing target in a processing chamber configured to accommodate a substrate for semiconductor manufacturing or a substrate for flat panel display manufacturing, and capable of controlling a processing state in each part of the processing target.

A substrate processing apparatus according to present disclosure comprises a processing chamber configured to accommodate a substrate for semiconductor manufacturing or a substrate for flat panel display manufacturing, a stage disposed in the processing chamber and on which the substrate is placed, a fluid supply source configured to supply processing fluid to the processing chamber to process the substrate, a plurality of cylindrical metallic resonators having a bottom portion and a lid, which are disposed in the processing chamber, a tube body made of a dielectric material, which extends along a central axis of each resonator, penetrates the resonator, and forms a fluid channel through which the processing fluid is supplied, a plurality of discharge holes provided in the processing chamber, each opening toward different positions of the substrate and connected to different fluid channels, and a plurality of microwave supply sources configured to supply microwaves to different resonators and activate the processing fluid within an activation region surrounded by the resonator in each fluid channel.

### BRIEF DESCRIPTION OF THE DRAWINGS

FIG. 1 is a longitudinal side view of a film forming apparatus according to a first embodiment of the present disclosure.

FIG. 2 is a longitudinal side view of a microwave reactor of the film forming apparatus.

FIG. 3 is a longitudinal perspective view of the microwave reactor.

FIG. 4 is explanatory diagram showing a process in the film forming apparatus of the first embodiment.

FIG. 5 is a longitudinal side view showing another configuration of the microwave reactor.

FIG. 6 is a longitudinal side view of a film forming apparatus according to a second embodiment of the present disclosure.

FIG. 7 is an explanatory diagram showing a process in the film forming apparatus of the second embodiment.

FIG. 8 is a longitudinal side view of a film forming apparatus according to a third embodiment of the present disclosure.

FIG. 9 is a longitudinal side view of a microwave reactor of the film forming apparatus of the third embodiment.

FIG. 10 is a longitudinal side view of a film forming apparatus according to a fourth embodiment of the present disclosure.

FIG. 11 is a longitudinal side view showing another configuration of the microwave reactor.

FIG. 12 is a longitudinal side view of a microwave reactor to which an electron supply part including an electrode and a high-frequency power supply is applied.

FIG. 13 is a longitudinal side view of a microwave reactor to which an electron supply part including an electrode and a high-frequency power supply is applied.

FIG. 14 is a longitudinal side view of a microwave reactor to which an electron supply part including an electrode and a high-frequency power supply is applied.

FIG. 15 is a longitudinal side view of a microwave reactor to which an electron supply part including an electrode and a high-frequency power supply is applied.

FIG. 16 is a longitudinal cross-sectional view of a microwave reactor to which an electron supply part of another configuration is applied.

FIG. 17 is a longitudinal cross-sectional view of a microwave reactor to which an electron supply part of still another configuration is applied.

FIG. 18 is an explanatory diagram showing a device configuration of an evaluation test.

FIG. 19 is a graph showing results of an evaluation test.

FIG. 20 is an explanatory diagram showing a device configuration of an evaluation test.

FIG. 21 is a graph showing results of the evaluation test.

FIG. 22 is an explanatory diagram showing a device configuration of an evaluation test.

FIG. 23 is a graph showing results of an evaluation test.

### DETAILED DESCRIPTION

### First Embodiment

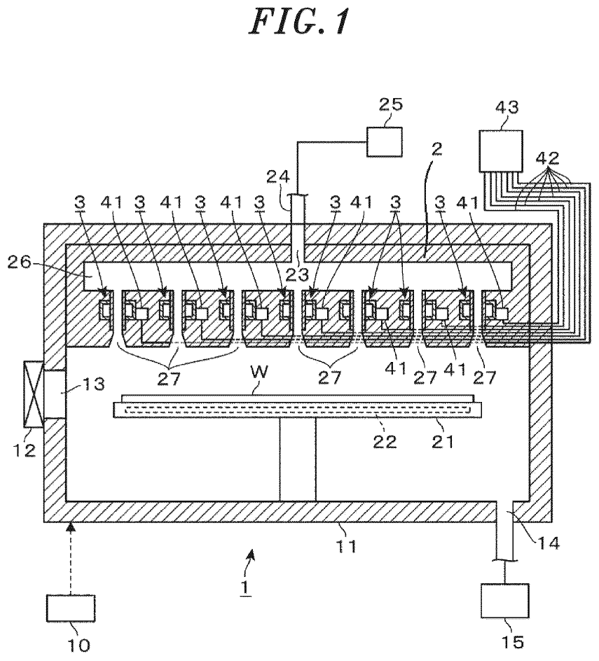

A film forming apparatus 1, which is an embodiment of a substrate processing apparatus of the present disclosure, will be described with reference to the longitudinal side view of FIG. 1. The film forming apparatus 1 includes a circular processing chamber 11. A transfer port 13 for a wafer W, which can be opened and closed by a gate valve 12, is formed in the sidewall of the processing chamber 11. An exhaust port 14 is opened, e.g., at the bottom portion of the processing chamber 11, and the exhaust port 14 is connected to an exhaust mechanism 15 through an exhaust line. The exhaust mechanism 15 includes a vacuum pump and a valve for adjusting an exhaust amount, and the processing chamber 11 is exhausted to a vacuum atmosphere of a desired pressure by the exhaust mechanism 15.

A stage 21 for horizontally placing a wafer W is provided in the processing chamber 11, and a heater 22 for heating the wafer W is embedded in the stage 21. The stage 21 is provided with lift pins (not shown), and the wafer W is transferred between the stage 21 and a transfer mechanism (not shown) for a wafer W, which moves into and out of the processing chamber 11, through the transfer port 13.

Next, the ceiling portion of the processing chamber 11 will be described. The ceiling portion of the processing chamber 11 is configured as a shower head 2 that supplies a gas to the wafer W in a shower pattern and has a circular shape in plan view. A gas inlet path 23 is formed vertically at the central portion of the shower head 2 in plan view. The shower head 2 is connected to the downstream end of a gas supply line 24 that supplies a gas to the gas inlet path 23, and the upstream side of the gas supply line 24 is connected to a gas supply source 25 that is a fluid supply source. The gas supply source 25 has a storage part that stores various gases, a valve, a mass flow controller, or the like, and supplies gases individually to the gas supply line 24. The gases to be supplied include a film forming gas that is a processing gas. The gas supply line 24 may be provided for each gas to be supplied.

The shower head 2 has a gas diffusion space 26 formed in a circular flat shape in plan view, for example, and the downstream end of the gas inlet path 23 is connected to the upper central portion of the diffusion space 26. Further, multiple sets of microwave supply source 41 and microwave reactor 3 that activate the gas supplied from the diffusion space 26 by the action of microwaves and are horizontally distributed below the diffusion space 26 of the shower head 2. discharge holes 27 are opened below the respective microwave reactors 3 on the bottom surface of the shower head 2. Therefore, the discharge holes 27 are opened toward different positions in the processing chamber 11, and the activated gas is supplied to different positions on the surface of the wafer W by the discharge holes 27. Hence, the diffusion space 26 is a space provided on the upstream side in common to the discharge holes 27.

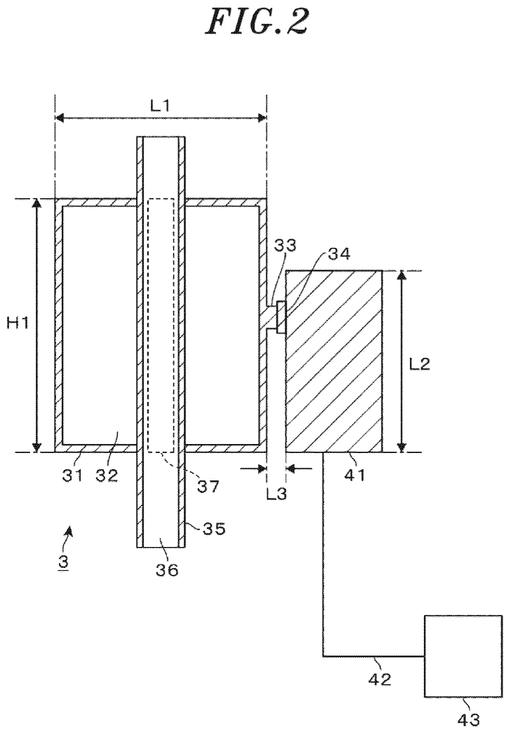

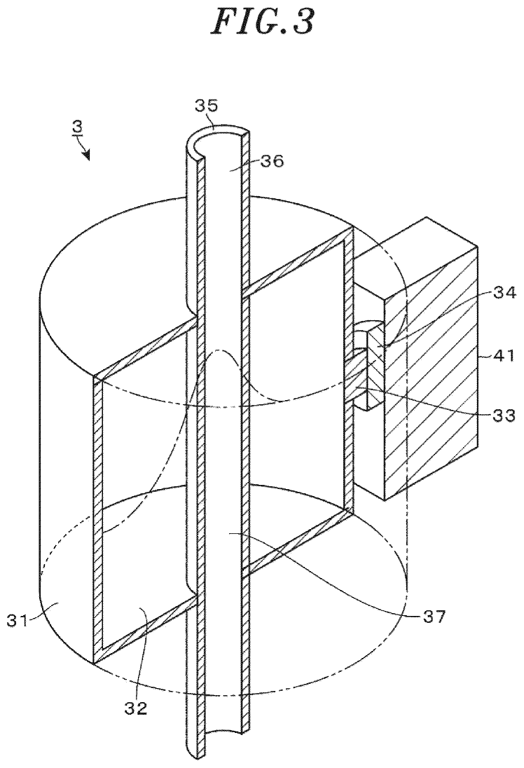

The microwave reactor 3 can activate the gas as described above. The activation includes heating and plasma generation. Hereinafter, the configuration of the microwave reactor 3 will be described with reference to the longitudinal side view of FIG. 2 and the longitudinal perspective view of FIG. 3.

The microwave reactor 3 includes a circular resonator 31 and a reaction tube 35 that is a circular tube. The resonator 31 is made of a metal, and is formed in a cylindrical shape with a bottom and a lid. In other words, the resonator 31 has a cylindrical sidewall and two end walls that are provided to close one end and the other end of the sidewall. Further, in FIG. 3, the outer shape of the resonator 31 at the cutout portion is indicated by dashed double-dotted lines. The resonator 31 is disposed at the shower head 2 such that the axial direction thereof extends along the vertical direction. As will be described later, microwaves are supplied from the sidewall of the resonator 31, and each end wall of the resonator 31 has a function of confining the energy of the microwaves in the region surrounded by the resonator 31.

The reaction tube 35, which is a tube body, is made of a dielectric material such as quartz, and is provided coaxially with the resonator 31 while penetrating through the resonator 31 in the axial direction. The inside of the reaction tube 35 serves as a gas channel 36. Therefore, the gas channel 36 extends along the central axis of the resonator 31, and penetrates through the resonator 31. The upper end of the gas channel 36 is connected to the diffusion space 26, and a gas is supplied from the diffusion space 26. Since an annular space 32 is disposed between the outer periphery of the reaction tube 35 and the resonator 31, the resonator 31 is configured as a so-called cavity resonator in this example. However, as will be described later, the space 32 is not necessarily provided.

On the sidewall of the resonator 31, a protrusion 33 is formed at an intermediate position in the axial direction of the resonator 31, and the resonator 31 and the microwave supply source 41 are connected via a connector 34 disposed at the protrusion 33. Therefore, the microwave supply source 41 is provided for each resonator 31, and the microwave supply source 41 is located near the resonator 31. The microwave supply source 41 includes a voltage-controlled oscillator (VCO) and a circuit for controlling the operation of the oscillator.

The resonator 31 may have an axial length H1 of, e.g., 5 mm to 100 mm, and an outer diameter L1 of, e.g., 20 mm to 100 mm. Further, a maximum length L2 of each side of the microwave supply source 41 is, e.g., 10 mm to 300 mm, and a distance L3 between the sidewall of the resonator 31 and the microwave supply source 41 is, e.g., 1 mm to 5000 mm. Each microwave supply source 41 is connected to a power supply part 43 provided outside the processing chamber 11, for example, via a cable 42. Alternatively, an antenna for power supply may be provided in the resonator 31 without using the cable 42, and the antenna and the power supply part 43 may be electrically connected. The power supply part 43 can control the power supplied to each microwave supply source 41. When it is necessary to cool the microwave supply source 41, an air-cooling fan or a water-cooling tube (not shown) may be provided at the shower head 2.

By supplying a power, microwaves, i.e., electromagnetic waves having a frequency of 300 MHz to 30 GHz, are supplied from the microwave supply source 41 to the resonator 31, and electric field distribution referred to as TM010 mode is generated. The electric field distribution is schematically indicated by a dashed line in FIG. 3. According to the distribution, the energy inside the reaction tube 35 is higher than that outside the reaction tube 35 in the resonator 31. In other words, energy is concentrated in the region of the gas channel 36 in the reaction tube 35, which is surrounded by the resonator 31, and the gas passing through the gas channel 36 is activated with high efficiency. The region surrounded by the resonator 31 in the gas channel 36, where the gas is activated, is illustrated as an activation region 37.

As the power supplied from the power supply part 43 to the microwave supply source 41 increases, the power of the microwaves outputted from the microwave supply source 41 increases, and the gas activation amount in the activation region 37 increases. In other words, the activity of the gas discharged from the microwave reactor 3 increases. Since the power supplied to each microwave supply source 41 is controlled as described above, the activity of the gas supplied to the discharge hole 27 from each microwave reactor 3 is controlled. Therefore, a gas can be supplied to each part on the surface of the wafer W such that desired activation distribution is obtained. In the film forming apparatus 1, a film having high in-plane uniformity in film thickness is formed on the surface of the wafer W. Hence, a test is performed in advance to determine a set value of the power supplied to each microwave supply source 41, for example. The wafer W is processed by supplying the power to each microwave supply source 41 at the set value. The shower head 2 including the microwave reactor 3, the gas supply line 24, the gas supply source 25, and the microwave supply source 41 described above constitute a fluid activation mechanism.

As shown in FIG. 1, the film forming apparatus 1 includes a controller 10 that is a computer (see FIG. 1), and the controller 10 includes a program. The program has commands (steps) so that the controller 10 can send control signals to individual components of the film forming apparatus 1 and execute processes to be described below. Specifically, the heating temperature of the wafer W by the heater 22 of the stage 21, the power supply from the power supply part 43 to each microwave supply source 41, the pressure in the processing chamber 11 by the exhaust operation of the exhaust mechanism 15, the supply of gases from the gas supply source 25, and the like are controlled by the program. The program is stored in a storage medium such as a compact disk, a hard disk, a memory card, or a DVD and is installed in the controller 10. Further, a control device (not shown) for controlling the operation of the power supply part 43 may be provided separately from the controller 10.

An operation for forming a TiN (titanium nitride) film on a wafer W by atomic layer deposition (ALD) will be described as an example of the processing operation of the film forming apparatus 1. In order to form the TiN film, the gas supply source 25 supplies TiCl4 (titanium tetrachloride) gas and NH3 (ammonia) gas, which are film forming gases, and N2 (nitrogen) gas, which is a purge gas for purging the inside of the processing chamber 11.

The wafer W is transferred into the processing chamber 11 and placed on the stage 21 by the transfer mechanism. When the transfer mechanism moves out of the processing chamber 11, the gate valve 12 is closed. The wafer W on the stage 21 is heated to a preset temperature by the heater 22 such that each part of the surface of the wafer W reaches a substantially uniform temperature. The inside of the processing chamber 11 is set to a vacuum atmosphere of a preset pressure by the exhaust from the exhaust port 14.

The power supply part 43 supplies a power set for each microwave supply source 41 to each microwave supply source 41, and each microwave supply source 41 emits microwaves of a power corresponding thereto. TiCl4 gas is supplied from the gas supply source 25, and flows from the diffusion space 26 to the gas channel 36 in the reaction tube 35 of each microwave reactor 3. The TiCl4 gas is heated in the activation region 37 of the gas channel 36, and is discharged from the discharge holes 27 to the wafer W.

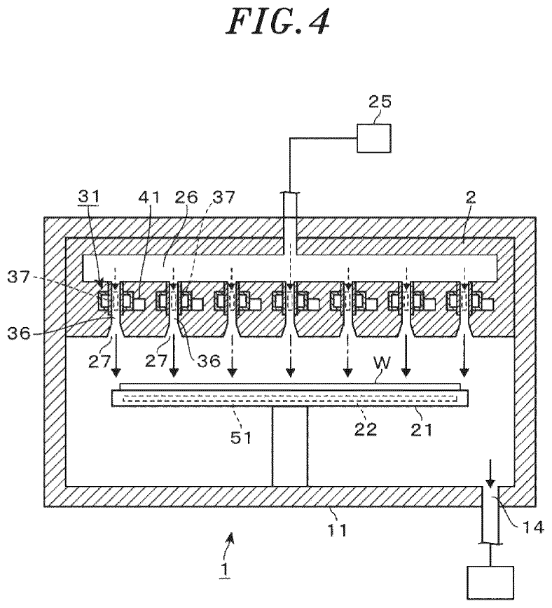

By individually activating gases in the respective microwave reactors 3, the TiCl4 gas discharged from the discharge holes 27 may have different temperatures. FIG. 4 is a schematic diagram of the film forming apparatus 1. In this example, when the temperature of the peripheral portion of the stage 21 is lower than that of the central portion thereof, TiCl4 gas having a low temperature is discharged to the central portion of the wafer W, and TiCl4 gas having a high temperature is discharged to the peripheral portion of the wafer W. The flows of the gases are indicated by arrows of different line types. The slight temperature difference at the respective parts on the surface of the wafer W, which is caused by the heating of the heater 22, is canceled by the temperature distribution of the TiCl4 gas, thereby further improving the temperature uniformity on the surface of the wafer W. As a result, the TiCl4 gas is adsorbed to the respective parts on the surface of the wafer W with high uniformity.

Then, the supply of TiCl4 gas from the gas supply source 25 is stopped, and N2 gas is supplied. The N2 gas discharged from the discharge holes 27 purges excess TiCl4 in the processing chamber 11. Next, NH3 gas is supplied from the gas supply source 25. Similarly to TiCl4 gas, the NH3 gas is individually activated in the microwave reactor 3 and discharged to the wafer W and adsorbed to the respective parts on the surface of the wafer W with high temperature uniformity. As a result, a thin layer of TiN is formed on the surface of the wafer W with high uniformity. Then, the supply of NH3 gas from the gas supply source 25 to the shower head 2 is stopped, and N2 gas is supplied. Thereafter, the N2 gas is discharged from the discharge holes 27 to purge the NH3 gas remaining in the processing chamber 11.

Next, the cycle of supplying TiCl4 gas to the wafer W, purging, supplying NH3 gas, and purging is repeated, so that a thin layer of TiN is laminated and becomes a TiN film. As described above, the TiN layer is formed with high uniformity in each part on the surface of the wafer W, thereby suppressing the variation in the thickness of the TiN film in each part on the surface of the wafer W. When the TiN film reaches a desired thickness, the cycle is stopped, and the wafer W is unloaded from the processing chamber 11 in the reverse order of the loading operation. When the purge gas is supplied, microwaves may or may not be supplied to the microwave reactor 3.

In accordance with the film forming apparatus 1, the plurality of microwave reactors 3 are provided to supply film forming gases (TiCl4 gas and NH3 gas) to different positions on the surface of the wafer W, and the film forming gases supplied to the respective parts on the surface of the wafer W are individually activated by the microwave supply sources 41 provided for the respective microwave reactors 3. Since the energy of the supplied microwaves can be concentrated with high efficiency in the activation region 37 in the reaction tube 35, the small microwave reactor 3 of which respective parts have the above-described sizes can be used. Therefore, the plurality of microwave reactors 3 can be provided in the processing chamber 11 as described above. Hence, the reactivity between the film forming gases and the wafer W can be individually controlled at each part of the wafer W. Accordingly, as described above, the TiN film can be formed to have a highly uniform film thickness at each part on the surface of the wafer W, for example.

Since the microwave reactor 3 can concentrate energy with high efficiency, it is not necessary to use a high-output microwave supply source 41, and the microwave supply source 41 may have a relatively small size as described above. Therefore, the microwave supply source 41 can be provided at the ceiling portion of the processing chamber 11 together with the microwave reactor 3, and can be disposed near the microwave reactor 3 as described above.

For example, instead of providing the microwave reactor 3 and the microwave supply source 41, it is possible to adopt a device configuration in which a relatively high-output and large microwave supply source is disposed outside the processing chamber 11 and microwaves are transmitted from the microwave supply source to a gas channel provided in the processing chamber 11 and activated. However, such a configuration requires a waveguide to transmit the microwaves from the outside of the processing chamber to the gas channel, which results in scaling up of the device configuration. Therefore, in accordance with the film forming apparatus 1, the arrangement of the waveguide becomes unnecessary by combining the plurality of small microwave reactors 3 configured as described above, thereby avoiding scaling up of the device configuration.

Further, it is difficult to precisely control the strength of the microwaves distributed to the respective microwave reactors 3 that are located relatively distant by the waveguide. For example, it is difficult to distribute the microwaves with equal strength to the respective microwave reactors 3. In other words, in a device configuration having a waveguide, it is relatively difficult to control the processing of the wafer W at each part on the surface of the wafer W. Therefore, the configuration of the film forming apparatus 1 in which the microwave supply sources 41 are located near the microwave reactors 3 and are arranged at the ceiling portion of the processing chamber 11 together with the microwave reactors 3 is advantageous in that the controllability of the processing at each part on the surface of the wafer W can be increased. In addition, the above-described Patent Document 1 discloses the heating of fluid by the microwave heating device having the cavity resonator, but does not disclose an apparatus including a plurality of heating devices or a configuration in which the heating device is applied to a substrate processing apparatus.

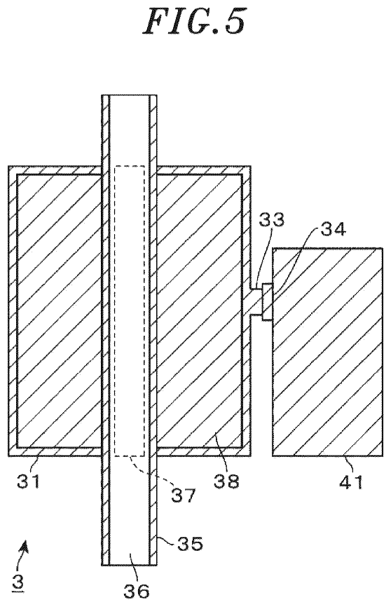

Although the microwave reactor 3 having a configuration in which the space 32 exists between the reaction tube 35 and the resonator 31 has been described, the present disclosure is not limited thereto. In the example shown in FIG. 5, a ring member 38 made of a dielectric material such as ceramic or the like is provided to surround the reaction tube 35, and the resonator 31 is formed to cover the ring member 38 from the outside. From another perspective, the above-described space 32 is filled with a dielectric material instead of a gas. By appropriately selecting the material of the ring member 38, which is a dielectric, the dielectric constant of the ring member 38 can be adjusted. By adjusting the dielectric constant, the energy concentrated in the gas channel 36 changes. In other words, by appropriately selecting the material of the microwave reactor 3, the scaling down can be reliably performed and further scaling up can be realized. Further, in the example of FIG. 5, the reaction tube 35 and the ring member 38 are separate bodies, but they may be integrally formed as a dielectric of the same material.

Further, the microwave supply source 41 is connected to the central portion in the axial length of the sidewall of the resonator 31, and microwaves are introduced from the central portion. However, the microwave introducing position may be shifted from the central portion in the axial direction. However, in order to concentrate energy in the activation region 37 with high efficiency, it is preferable that the microwave supply source 41 is connected to the central portion in the axial direction as described above, and the microwaves are introduced from the central portion.

In the above processing example, the film forming gas is heated in the activation region 37 of the microwave reactor 3 without being turned into plasma. However, discharge may occur by making the power of microwaves to be supplied relatively high, so that the film forming gas may be turned into plasma. In other words, microwaves of individual powers are supplied to the respective microwave reactors 3, and plasma of the film forming gases with different intensities is generated in the respective activation regions 37. By supplying plasma components with different intensities to the wafer W, the reaction between each gas and the wafer W at each part on the surface of the wafer W is controlled, and the film thickness at each part on the surface can be controlled. When the plasma is generated in the microwave reactor 3, the activation region 37 corresponds to the plasma generation region.

However, the present disclosure is not limited to a case in which the gas activation in the microwave reactor 3 is controlled such that the film thickness distribution becomes uniform at each part on the surface of the wafer W. In other words, the activation amount may be controlled such that the film thickness becomes different at the respective parts on the surface of the wafer W. More specifically, for example, the gas activation may be performed by each microwave reactor 3 such that the film thickness at one of the peripheral portion of the wafer W and the central portion of the wafer W becomes larger than the other portion.

Although the ALD process in which TiCl4 gas and NH3 gas are alternately supplied has been described, a TiN film may be formed by a CVD process in which TiCl4 gas and NH3 gas are supplied simultaneously. In addition, the process performed on the wafer W is not limited to film formation, and etching may be performed by activating an etching gas as a processing gas in the microwave reactor 3 and supplying it to the wafer W. For example, ClF3 gas may be supplied as an etching gas from the gas supply source 25, activated in the microwave reactor 3, and supplied to the wafer W to etch a Si film on the surface of the wafer W. Also in the case of performing etching, it is not necessary to activate the gas such that the etching amount becomes uniform at each part on the surface of the wafer W, and the gas may be activated such that the etching amount of one of the peripheral portion of the wafer W and the center portion of the wafer W becomes greater than the etching amount of the other portion, for example. In the case of performing etching, similarly to the case of performing film formation, the gas in the microwave reactor 3 may be activated only by heating, or may be activated to produce plasma. Next, an example of using the film forming apparatus 1 for forming a film other than a TiN film will be described. SiH4 (silane) gas is supplied from the gas supply source 25 to the microwave reactor 3, and the gas is heated in the microwave reactor 3 to a temperature of, e.g., 450° C. or less to generate Si2H6 (disilane) gas. Then, the Si2H6 gas is supplied to the wafer W to form an amorphous silicon film by CVD. In the case of forming an amorphous silicon film by an apparatus capable of performing plasma CVD, the film formation rate (the film formation amount per unit time) is higher in the case of using Si2H6 gas as a film formation source gas than in the case of using SiH4 gas. Therefore, the film formation rate can be increased by converting SiH4 gas into Si2H6 gas using the microwave reactor 3 and supplying it to the wafer W as described, which is preferable. The apparatuses of the following embodiments can also be applied to the formation of the amorphous silicon film.

### Second Embodiment

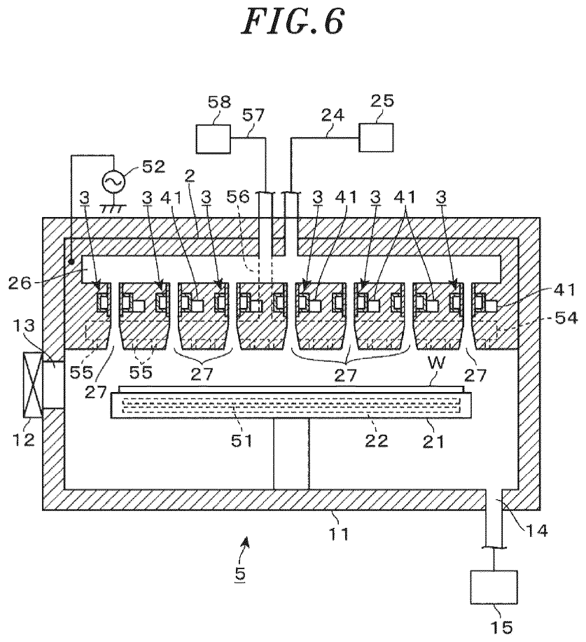

Next, a plasma film forming apparatus 5 according to a second embodiment will be described with reference to FIG. 6 mainly based on the differences from the film forming apparatus 1. The plasma film forming apparatus 5 produces capacitively coupled plasma of a film forming gas, and performs film formation by exposing a wafer W to the plasma. The capacitively coupled plasma is produced by a mechanism different from a mechanism for generating plasma using the microwave reactor 3.

A gas for plasma production is supplied as a processing gas to each microwave reactor 3, for example, and plasma of an individual intensity is generated in each microwave reactor 3. The components of the plasma are supplied to the capacitively coupled plasma. By supplying the plasma of gas from the microwave reactor 3, the intensity distribution of the capacitively coupled plasma at each part is adjusted. Accordingly, the processing state at each part on the surface of the wafer W is controlled, and desired film thickness distribution is obtained.

Hereinafter, the specific configuration of the plasma film forming apparatus 5 will be described. An electrode 51 is embedded in the stage 21, and the shower head 2 also serves as an electrode facing the electrode 51. In other words, the electrode 51 and the shower head 2 constitute parallel plate electrodes for generating capacitively coupled plasma. A high-frequency power supply 52 is connected to the shower head 2, and a high-frequency power is supplied thereto. The high-frequency power supply 52 and the electrode 51 correspond to a plasma producing mechanism.

The microwave reactor 3 have the same configuration as that of the first embodiment, and the cable 42 and the power supply part 43 are omitted in FIG. 6 to avoid complicated illustration. In the shower head 2, a flat gas diffusion space 54 having a circular shape in plan view is provided below the region where the microwave reactor 3 and the microwave supply source 41 are provided, for example. Further, a plurality of discharge holes 55 connected to the diffusion space 54 are distributed and opened on the bottom surface of the shower head 2. The downstream end of a gas inlet 56 extending upward through the shower head 2 is connected to the upper central portion of the diffusion space 54. The upstream end of the gas inlet 56 is connected to the downstream end of a gas supply line 57, and the upstream end of the gas supply line 57 is connected to a gas supply source 58.

The channel formed by the diffusion space 54, the gas inlet 56, and the discharge holes 55, which is connected to the gas supply source 58, is partitioned from the channel formed by the gas inlet path 23, the diffusion space 26, the microwave reactor 3, and the discharge holes 27 in the shower head 2, which is connected to the gas supply source 25 described in the first embodiment. Therefore, the gas supplied from the gas supply source 58 and the gas supplied from the gas supply source 25 are discharged from the shower head 2 without being mixed in the shower head 2.

An operation for forming a Ti (titanium) film on a wafer W by chemical vapor deposition (CVD) will be described as an example of the processing operation of the plasma film forming apparatus 5. In order to form the Ti film, the gas supply source 25 supplies Ar (argon) gas as a film forming gas, and the gas supply source 58 supplies Ar gas and TiCl4 gas as film forming gases, and H2 gas as a reducing gas.

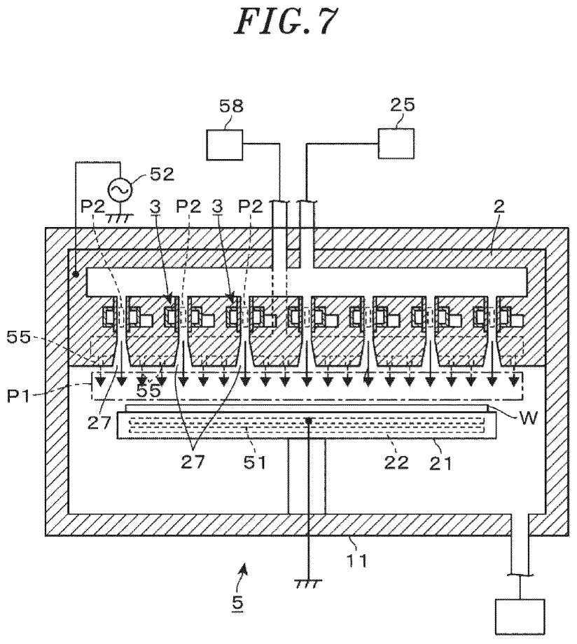

Similarly to the film formation by the film forming apparatus 1, the wafer W is heated to a preset temperature by the heater 22 of the stage 21, and the inside of the processing chamber 11 is set to a vacuum atmosphere of a preset pressure. Then, TiCl4 gas, H2 gas, and Ar gas are supplied from the gas supply source 58, and discharged from the discharge holes 55 of the shower head 2 as indicated by dotted arrows in FIG. 7. Further, the high-frequency power is supplied from the high-frequency power supply 52 to the shower head 2. As a result, plasma P1, which is the capacitively coupled plasma, is produced on the entire surface of the wafer W, and reaction occurs between the plasma P1 and the wafer W. Specifically, TiCl4 is deposited on the wafer W, and Ti is generated by the reduction of TiCl4.

Meanwhile, Ar gas is supplied from the gas supply source 25 to each microwave reactor 3, and microwaves are supplied to the resonator 31, thereby generating plasma P2 in the activation region 37. Then, as indicated by solid arrows in FIG. 7, the components of the plasma P2 are discharged from the discharge holes 27 to the plasma P1, and the intensity of the plasma P1 at each part is adjusted as described above. By adjusting the intensity, the reactivity between the plasma P1 and the wafer W at each part of the wafer W is controlled, and desired film thickness distribution can be obtained on the surface of the wafer W as described above. In this manner, the plasma film forming apparatus 5 also has the effect of controlling the processing state at each part on the surface of the wafer W, similarly to the film forming apparatus 1. Further, by providing the microwave reactor 3, the scaling up of the apparatus is prevented, similar to the case of the film forming apparatus 1.

As described in the second embodiment, a gas that produces plasma, such as Ar gas, is also included in the processing gas. Also in the second embodiment, etching can be performed by supplying an etching gas instead of a film forming gas, similarly to the first embodiment. In other words, the plasma P1 is produced by the etching gas, and the intensity distribution of the plasma Pl is adjusted by the plasma of gas supplied from the microwave reactor 3, thereby controlling the amount of etching at each part on the surface of the wafer W.

### Third Embodiment

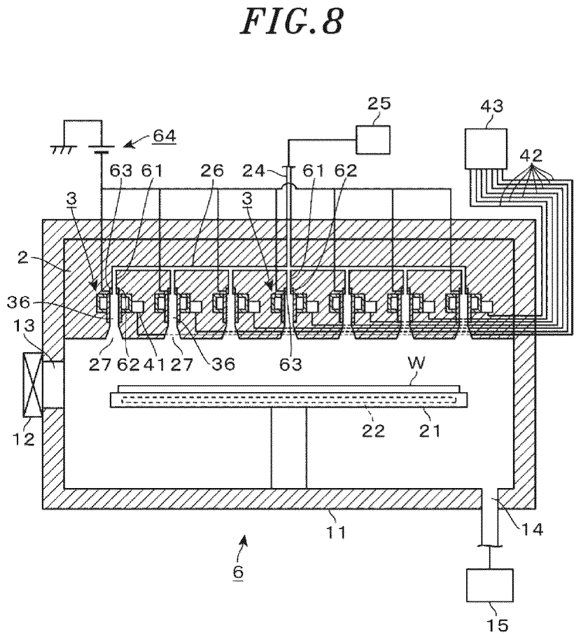

Next, a film forming apparatus 6 according to a third embodiment will be described with reference to FIG. 8 mainly based on the differences from the film forming apparatus 1 of the first embodiment. The film forming apparatus 6 forms a TiN film on the wafer W by ALD, similarly to the film forming apparatus 1. Therefore, in the film forming apparatus 6, the gas supplied from the gas supply source 25 to the shower head 2 are the same as that supplied in the film forming apparatus 1. However, in the microwave reactor 3, the plasma is produced from TiCl4 gas and NH3 gas.

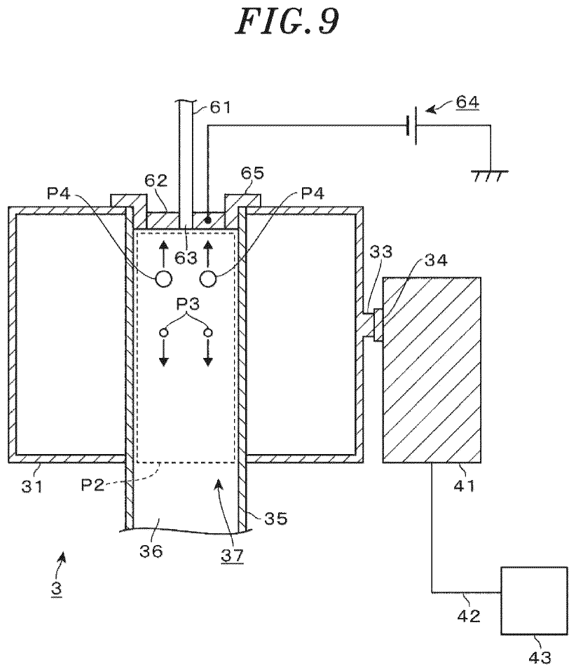

In the film forming apparatus 6, a plurality of channels extend downward from positions overlapping the reaction tubes 35 in the diffusion space 26 of the shower head 2. On the assumption that such a channel is defined as an upstream channel 61, the downstream end of the upstream channel 61 and the upstream end of the gas channel 36 of the reaction tube 35 are connected to each other through a channel 63 formed in an electrode 62. A DC power supply 64 is connected to the electrodes 62. In this example, the electrodes 62 serves as cathodes. The shower head 2 is grounded via the processing chamber 11, and the walls of the discharge holes 27 of the shower head 2 serve as anodes. The DC power supply 64 includes, e.g., a voltage controller (not shown), and can control the voltage applied to each electrode 62. The configuration of the electrode 62 will be further described with reference to FIG. 9. The electrode 62 is a circular ring, and is disposed in the upper end of the reaction tube 35. A cylindrical portion 65 made of an insulator is interposed between the electrode 62 and the inner wall of the reaction tube 35, and the electrode 62 is fixed to the lower end of the cylindrical portion 65. The upper end of the cylindrical portion 65 expands outward to be formed as a flange supported by the upper end wall of the resonator 31. Therefore, the cylindrical portion 65 surrounds the side circumference of the electrode 62 to insulate the electrode 62 from the resonator 31, and the electrode 62 is provided to close the upstream end of the activation region 37 surrounded by the resonator 31 in the reaction tube 35. A small-diameter through-hole is formed in the central portion of the electrode 62 to penetrate through the electrode 62 in a thickness direction, and serves as the channel 63.

In the film forming apparatus 6, similarly to the film forming apparatus 1, a cycle of supplying TiCl4 gas and NH3 gas and purging is repeated, thereby processing the wafer W. In this cycle, when TiCl4 gas and NH3 gas are supplied to each microwave reactor 3, the power of the microwaves supplied from each microwave supply source 41 is controlled such that plasma P2 is produced in the activation region 37 of the gas channel 36 of the reaction tube 35.

During the production of the plasma P2 of TiCl4 gas or NH3 gas, a DC voltage is applied to each electrode 62. Electrons P3 forming the plasma P2 repel the electrode 62 to which the DC voltage is applied, and then are pushed out from the activation region 37 toward the discharge holes 27 and supplied to the wafer W. The radicals (not shown) forming the plasma P2 are also supplied to the wafer W from the discharge holes 27. On the other hand, ions P4 forming the plasma P2 are attracted to the electrode 62, so that the supply of the ions 4 to the wafer W is suppressed. Therefore, between the electrons P3 and the ions P4, the electrons P3 are selectively supplied to the wafer W. Hence, in accordance with the film forming apparatus 6, in addition to the effect of the film forming apparatus 1, it is possible to improve the film quality of the TiN by suppressing the supply of relatively high energy of the ions P4 to the surface of the wafer W.

### Fourth Embodiment

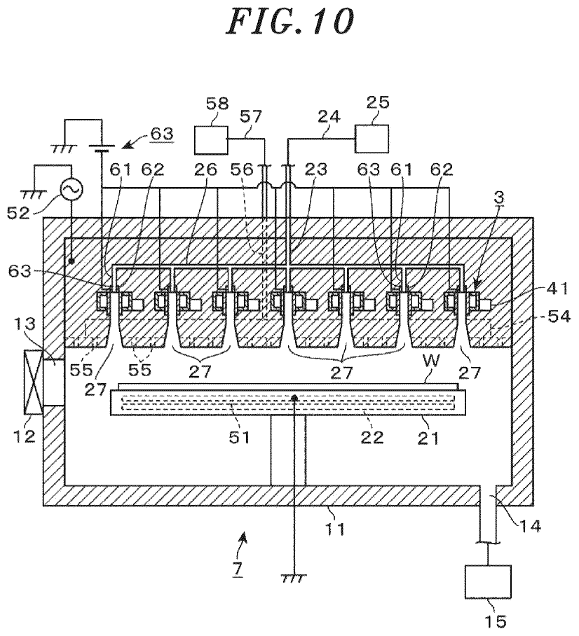

Next, a plasma film forming apparatus 7 according to a fourth embodiment will be described with reference to FIG. 10 mainly based on the differences from the plasma film forming apparatus 5 of the second embodiment. In the plasma film forming apparatus 7, similarly to the film forming apparatus 6 of the third embodiment, the downstream end of the upstream channel 61, of which upstream side is connected to the diffusion space 26, and the upstream end of the gas channel 36 of the reaction tube 35 are connected to each other via the channel 63 formed in the electrode 62. The electrode 62 is connected to the DC power supply 64 and serves as the cathode.

In the plasma film forming apparatus 7, similarly to the plasma film forming apparatus 5, Ar gas, TiCl4 gas, and H2 gas are supplied from the gas supply source 58 to the wafer W, thereby producing the plasma P1 that is capacitively coupled plasma. On the other hand, in the microwave reactor 3, the plasma P2 is produced from the Ar gas supplied from the gas supply source 25, and the intensity distribution of the plasma P1 is adjusted. When the plasma P2 is produced, a DC voltage is applied to the electrode 62 as described in the third embodiment, and ions forming the plasma P2 are attracted to the electrode 62. Accordingly, electrons are selectively discharged from the discharge holes 27. Hence, in addition to the effects of the plasma film forming apparatus 5, the plasma film forming apparatus 7 can suppress the deterioration of the quality of the Ti film due to ions. Further, the ion attraction amount changes depending on the DC voltage applied to the electrode 62, so that the intensity of the plasma P1 below the electrode 62 can be controlled. Therefore, in accordance with the plasma film forming apparatus 7, the distribution of the intensity of the plasma P1 can be controlled by the DC voltage applied to each electrode 62, in addition to the power of the microwaves supplied to each microwave reactor 3. As a result, it is possible to more reliably control the processing at each part on the surface of the wafer W, which is preferable.

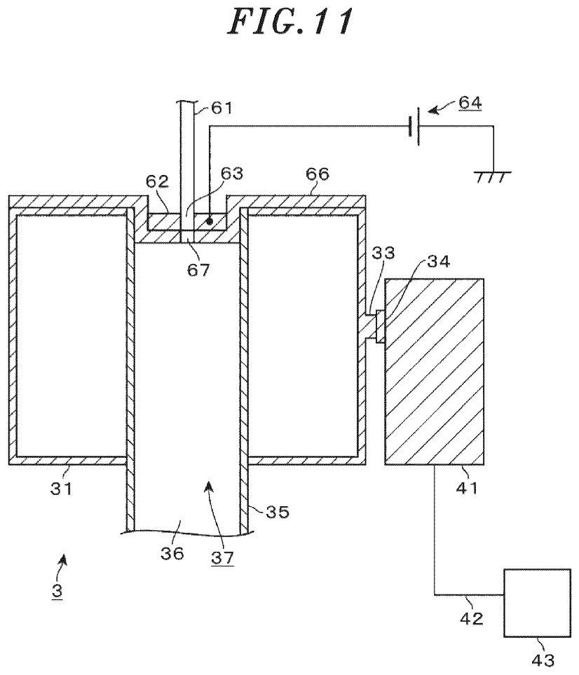

FIG. 11 shows another example of the configuration of the microwave reactor 3 including the electrode 62 to which the DC voltage is applied. In this example, a cover 66 that is an insulator covers the upper end of the reaction tube 35, and is supported on the upper end surface of the resonator 31. The cover 66 is recessed into the reaction tube 35, and the electrode 62 is provided to overlap a position above the recess. Therefore, the electrode 62 is provided to block the upstream end of the activation region 37 of the reaction tube 35 together with the cover 66. A through-hole 67 is formed at a position of the cover 66 that overlaps the channel 63 of the electrode 62, and the gas supplied from the upstream channel 61 is supplied to the gas channel 36 of the reaction tube 35 through the channel 63 and the through-hole 67. The electrode 62 does not necessarily form a gas channel as shown in FIG. 11 and FIG. 9, as long as electric field can be generated in the reaction tube 35.

Also in the third and fourth embodiments in which ions are attracted to the electrode 62, an etching gas is supplied instead of a film forming gas as described in the first and second embodiments, so that the etching apparatus may be used. Further, in the third and fourth embodiments, the same DC voltage may applied to each electrode 62, but it is preferable to apply DC voltages of individual values as described above so that the processing at each part on the surface of the wafer W can be controlled.

The electrode 62 may be connected to the DC power supply 64 to serve an anode. Therefore, between electrons and ions forming the plasma produced in the microwave reactor 3, ions may be selectively supplied to the wafer W. For example, the etching apparatus may be used in the third and fourth embodiments. In this case, by selectively supplying ions, the energy applied to the wafer W in the case of performing, e.g., etching increases, so that the etching rate increases and the processing can be completed quickly.

In the second and fourth embodiments in which capacitively coupled plasma is produced, the capacitively coupled plasma may be generated by connecting the high-frequency power supply 52 to the electrode 51 of the stage 21 instead of the shower head 2. Further, the plasma produced between the stage 21 and the shower head 2 is not limited to the capacitively coupled plasma. For example, inductively coupled plasma may be produced by supplying a high-frequency power to the shower head 2 provided with a conductive member such as an antenna or the like.

The distribution of the power supplied to the microwave supply sources 41 may be constant for each processing. However, in the case of performing film formation, for example, whenever the processing is performed on the wafer W, the thickness of the film adhered to the inner wall of the processing chamber 11 changes, and the environment in the processing chamber 11 changes. In order to cancel the influence of the changes in the environment, the distribution of the power supplied to the microwave supply sources 41 may be changed for each processing.

Further, it is not necessary to provide one microwave supply source 41 for one microwave reactor 3. One microwave supply source 41 may be connected to the plurality of microwave reactors 3, and multiple sets of the plurality of microwave reactors 3 and one microwave supply source 41 may be provided. Further, the set of the microwave reactors 3 and the microwave supply source 41 is not necessarily provided at the ceiling portion of the processing chamber 11. For example, the multiple sets thereof be provided on the sidewall of the processing chamber 11, and an activated gas may be supplied to each part on the surface of the wafer W through a gas channel extending from the sidewall to the shower head 2.

In the case of producing plasma by causing discharge in the activation region 37, a relatively high microwave power may be required depending on types of gases to be supplied to the microwave reactor 3 or the pressure in the processing chamber 11. In other words, the range of the power that can produce plasma may be narrow. An electron supply part that supplies electrons to facilitate production of plasma in the activation region 37 may be provided so that plasma can be produced in the activation region 37 even with a relatively low microwave power. If plasma can be produced even with a relatively low microwave power, parameters, such as a flow rate of a gas to be supplied to the reaction tube 35 and a pressure in the reaction tube 35, can be set over a wide range, or more various gases can be used.

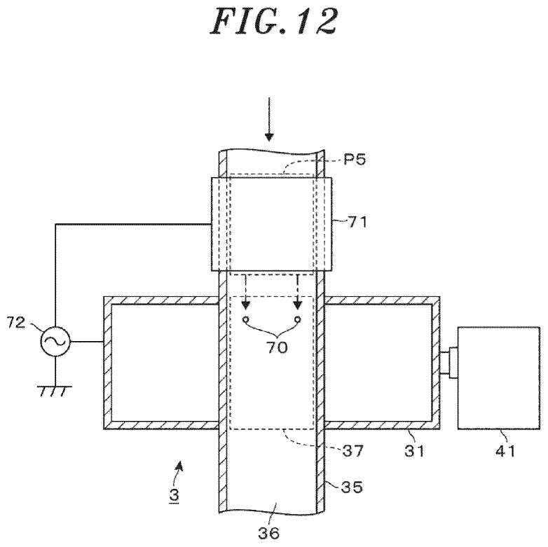

The electron supply part can be applied to the apparatus of each of the above-described embodiments. Hereinafter, an example of the electron supply part will be described in detail. The solid arrows in FIGS. 12 to 17 indicate the flow of the processing gas supplied to the reaction tube 35. In the configuration example of FIG. 12, an electrode 71 is provided at the outer circumference of the reaction tube 35. More specifically, the electrode 71 is provided to surround a portion of the reaction tube 35 that forms the upstream channel with respect to the activation region 37. A high-frequency power supply 72 is connected to the electrode 71 and the resonator 31. The high-frequency power supply 72 and the electrode 71 constitute the electron supply part.

When the processing gas is supplied to the reaction tube 35, the high-frequency power is supplied to the electrode 71 by the high-frequency power supply 72, and electric field is generated at a portion of the gas channel 36 of the reaction tube 35 that is surrounded by the electrode 71. Accordingly, discharge occurs, and plasma P5 is produced. Hereinafter, for convenience of description, the discharge and the plasma on the upstream side of the activation region 37 may be referred to as “preliminary discharge” and “preliminary discharge plasm”, respectively. Electrons 70 forming the preliminary discharge plasma P5 are supplied to the activation region 37.

Simultaneously with the supply of the high-frequency power from the high-frequency power supply 72, microwaves are supplied to the microwave reactor 3 as described in each of the above-described embodiments. By supplying the electrons 70 to the activation region 37 in a state where the energy of the processing gas in the activation region 37 has increased by the microwaves, discharge is caused to turn the processing gas into plasma. In other words, plasma (may also referred to as “main plasma” for convenience of description) having an intensity higher than that of the preliminary discharge plasma P5 is produced, and the components of the main plasma are discharged from the discharge holes 27 to process the wafer W. The high-frequency power supply 72 may be shared by the microwave reactors 3, or the high-frequency power supply 72 may be provided for each microwave reactor 3.

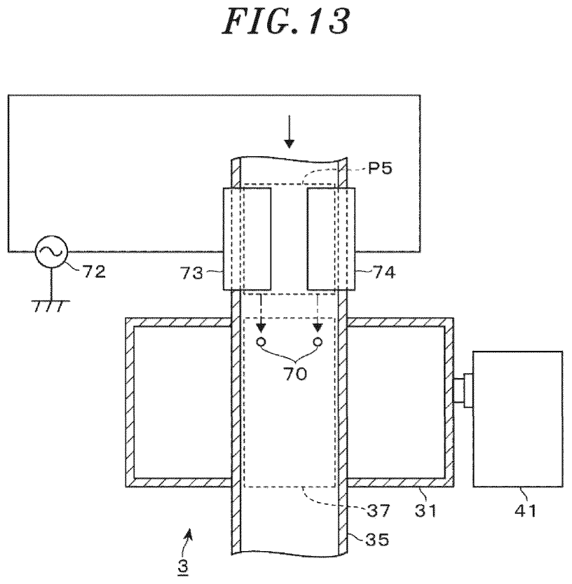

FIG. 13 shows another example of a configuration in which the preliminary discharge plasma P5 is produced. In the example of FIG. 13, electrodes 73 and 74 are provided at the outer circumference of the reaction tube 35 instead of the electrode 71, and constitute the electron supply part together with the high-frequency power supply 72. The electrodes 73 and 74 are provided with a portion of the reaction tube 35 that forms an upstream channel of the activation region 37 interposed therebetween, and are connected to the high-frequency power supply 72. The electrodes 73 and 74 and the high-frequency power supply 72 constitute the electron supply part. By supplying the high-frequency power from the high-frequency power supply 72, electric field is generated in the region between the electrodes 73 and 74 of the gas channel 36 of the reaction tube 35. Accordingly, preliminary discharge occurs, and the preliminary discharge plasma P5 is produced. Due to the electrons 70 of the preliminary discharge plasma, main plasma is generated in the activation region 37.

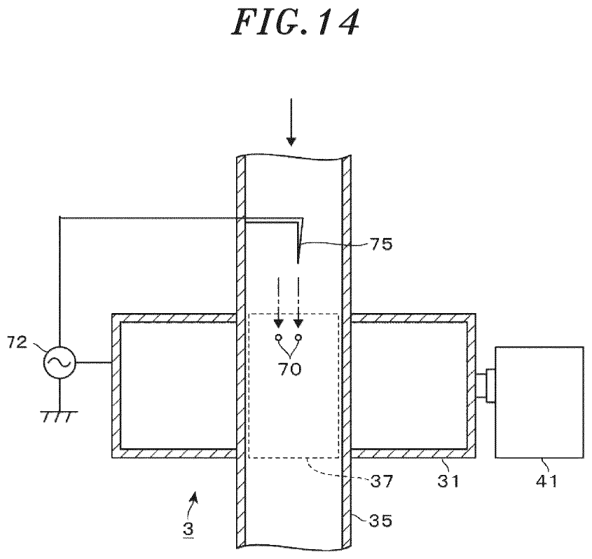

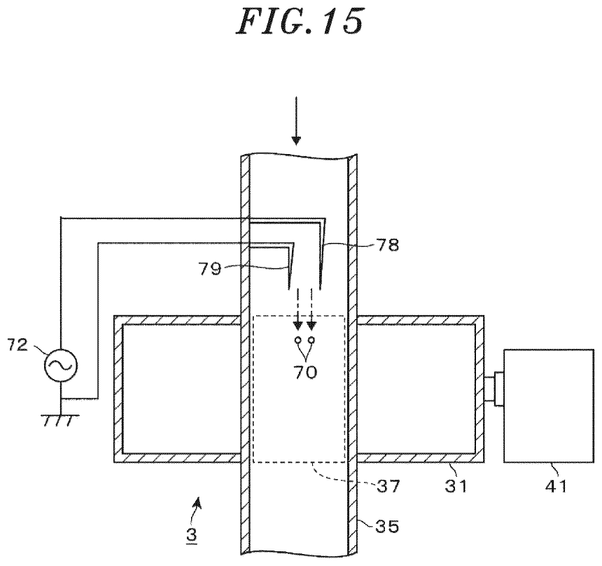

Next, another configuration example in which preliminary discharge occurs is shown in FIG. 14. In the example shown in FIG. 14, a needle-shaped electrode 75 is provided in the reaction tube 35. The example of FIG. 14 has the same configuration as the example of FIG. 12 except that the electrode 75 is provided instead of the electrode 71. Therefore, the high-frequency power supply 72 is connected to the electrode 75 and the resonator 31. The preliminary discharge occurs around the electrode 75, and the electrons 70 are supplied to the activation region 37. In the example shown in FIG. 15, needle-shaped electrodes 78 and 79 are provided in the reaction tube 35. The example of FIG. 15 has the same configuration as the example of FIG. 13 except that the electrodes 78 and 79 are provided on the upstream side of the activation region 37 in the reaction tube 35 instead of the electrodes 73 and 74. Hence, the high-frequency power supply 72 is connected to the electrodes 78 and 79. Preliminary discharge occurs between the electrodes 78 and 79, and the electrons 70 are supplied to the activation region 37.

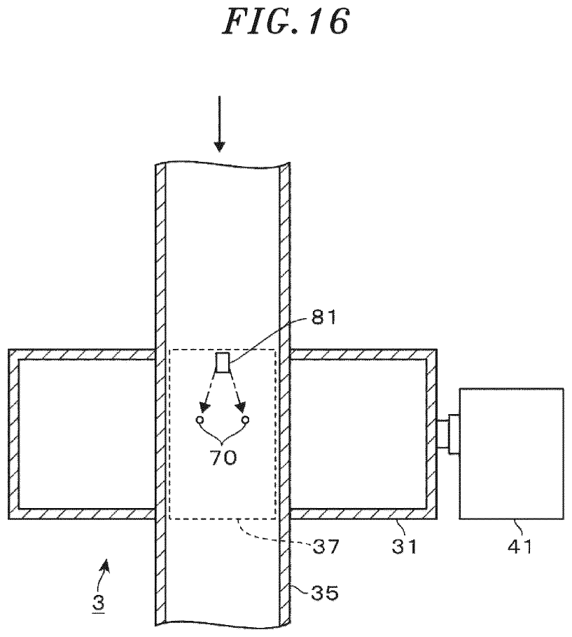

The electron supply part does not necessarily cause preliminary discharge, and does not necessary generate electrons on the upstream side of the activation region 37. FIG. 16 shows an example in which a metal piece (metal part) 81 is provided as an electron supply part at a portion of the inner wall of the reaction tube 35 that forms the activation region 37. The metal piece 81 is heated by the supply of microwaves from the microwave supply source 41 and emit the electrons 70, thereby producing plasma in the activation region 37. Therefore, the metal piece 81 is a source of thermoelectrons, and is made of a metal, e.g., tungsten, that is likely to emit thermoelectrons.

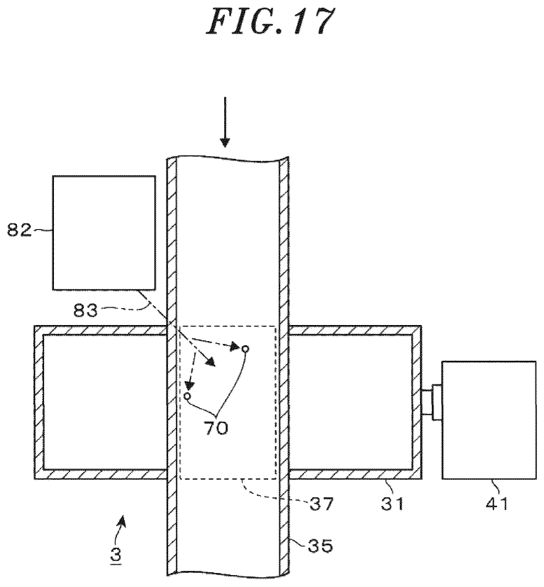

In the example shown in FIG. 17, an ultra violet (UV) lamp 82, which is a photon supply part, is provided as an electron supply part outside the reaction tube 35. UV light 83 containing high-energy photons, which is irradiated from the UV lamp 82, transmits through the reaction tube 35 and is supplied to the activation region 37. Accordingly, molecules of the processing gas are excited to generate the electrons 70, and plasma is produced. Further, the region where the electrons 70 are generated by the irradiation of the UV light 83 may be located on the upstream side of the activation region 37.

Although FIG. 17 shows that the UV lamp 82 is located near the microwave reactor 3, the present disclosure is not limited thereto. For example, the UV lamp 82 may be provided on the ceiling plate of the processing chamber 11, which is relatively distant from the microwave reactor 3, and may irradiate the UV light 83 to the activation region 37 or the upstream side adjacent thereto via a light-guiding member such as an optical fiber or the like. X-rays, gamma rays, or the like may be supplied instead of UV light, as long as high-energy photons can be supplied. In other words, the photon supply part may supply electromagnetic waves with a wavelength different from that of the microwaves supplied to the resonator 31 to generate electrons.

When the electrons are generated on the upstream side of the activation region 37 by the electron supply part, the electrons are not necessarily generated in the reaction tube 35, i.e., in a channel surrounded by a dielectric. In addition, as an example of a component for facilitating plasma production in the activation region 37, a dielectric member made of ceramic may be provided in the reaction tube 35, for example. The dielectric member is disposed to protrude toward the activation region 37 in the reaction tube 35, and has a rod shape, for example, to affect the electric field distribution. Such a configuration will be further described later together with the description of the evaluation test.

Although the wafer W is processed as the substrate in the above-described apparatus, the substrate to be processed is a substrate for semiconductor manufacturing or a substrate for flat panel display (FPD) manufacturing. The substrate for semiconductor manufacturing includes a substrate used in a semiconductor manufacturing process, in addition to the wafer W. The substrates for FPD manufacturing includes various flat panel displays such as a liquid crystal display, a plasma display, an organic electroluminescence (EL) display, a field emission display, or an electronic paper, and a substrate used in the FPD manufacturing process. The substrates used in the semiconductor manufacturing process and the substrates used in the FPD manufacturing process include a substrate that is a photomask used in an exposure processes during the respective manufacturing processes, and a dummy substrate that is processed for testing or processing parameter setting in the substrate processing apparatus.

Although the case in which the microwaves are introduced from the sidewall of the resonator 31 has been described, the microwaves are not necessarily introduced from the sidewall.

In other words, the microwave supply source 41 may be connected to the end wall forming the bottom portion of the resonator 31 or the end wall forming the lid of the resonator 31, and the microwaves may be introduced from any one end wall to activate a gas in the region of the gas channel 36 that is surrounded by the resonator 31.

Although the case in which the microwave reactor 3 activates the gas supplied from the gas supply source 25 has been described, the present disclosure is not limited thereto. Liquid may be supplied from a liquid supply source to the microwave reactor 3, and activated and supplied to the substrate in the processing chamber 11 to perform processing. For example, a heating mechanism for heating a channel extending from the liquid supply source to the microwave reactor 3 is provided. The liquid may be heated by the heating mechanism, supplied in the form of mist to the microwave reactor 3, and activated in the microwave reactor 3. The mist may be activated in the microwave reactor 3 and supplied in the form of a gas or plasma to the substrate, or may be supplied in the form of mist to the substrate in a state where the temperature has increased due to activation.

Further, although the case in which the microwave reactor 3 activates processing fluid (liquid and gas) that is supplied to the substrate and used for processing has been described, it is not necessary to activate the processing fluid used for processing the substrate. For example, in a state where the substrate for semiconductor manufacturing and the substrates for FPD manufacturing described above are not stored in the processing chamber 11, a cleaning gas is supplied from the gas supply source 25, activated by the microwave reactor 3, and supplied into the processing chamber 11. The activated cleaning gas may be used to clean the components of the device such as the stage 21 or the inner wall of the processing chamber 11. In the case of cleaning individual components in the processing chamber 11, similarly to the case of processing the wafer W, the gas supplied to a processing target (individual components in the processing chamber 11 in this case) can be individually activated. Therefore, by increasing the degree of gas activation in locations of the processing chamber 11 where a large amount of foreign substance is expected to accumulate, and decreasing the degree of gas activation in other locations, the cleaning can be reliably performed while suppressing power consumption. As described above, the fluid to be activated includes fluid other than the processing fluid for processing the substrate, and the fluid may be supplied to the processing chamber in which the substrate for semiconductor manufacturing and the substrate for FPD manufacturing are stored and processed. The target processed by the fluid includes a target other than the substrate.

It should be noted that the above-described embodiments are illustrative in all respects and are not restrictive. The above-described embodiments may be omitted, replaced, changed, or combined in various forms without departing from the scope of the appended claims and the gist thereof.

### Evaluation Tests

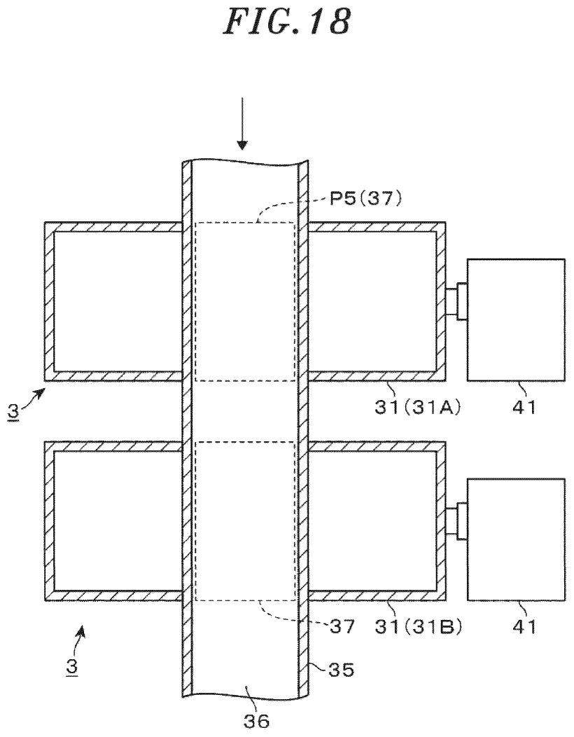

Evaluation tests related to the present disclosure will be described. In evaluation test 1, as shown in FIG. 18, the resonators 31 were provided on the upstream and downstream sides of the reaction tube 35, and microwaves were supplied from the microwave supply sources 41 to the resonators 31. For convenience of description, they are referred to as “upstream resonator 31A” and “downstream resonator 31B.” The upstream resonator 31A is a resonator for producing the preliminary discharge plasma P5, and the downstream resonator 31B is a resonator for producing the main plasma.

In the evaluation test 1, the power of microwaves capable of causing discharge in the resonator 31B was measured in order to examine the difference in the power of the microwaves depending on the presence or absence of the preliminary discharge plasma P5 produced by the resonator 31A. The power was measured under different pressure conditions by changing the pressure in the reaction tube 35 within a range higher than 0 kPa and lower than 15 Pa. The measurement performed in a state where the preliminary discharge plasma P5 was not produced was set as evaluation test 1-1, and the measurement performed in a state where the preliminary discharge plasma P5 was produced was set as evaluation test 1-2. As the measurement conditions, Ar gas was supplied to the reaction tube 35 at 30 sccm. Further, in evaluation test 1-2, discharge was caused in a state where the pressure of the gas channel 36 in the reaction tube 35 was set to 1.48 kPa and, then, the microwave power was set to 50 W to maintain the discharge in the activation region 37 of the resonator 31A.

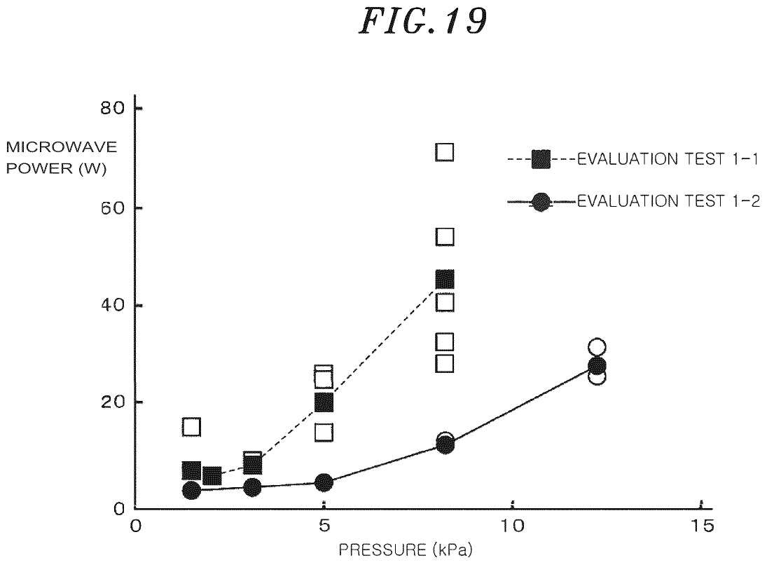

FIG. 19 is a graph showing the results of the evaluation test 1. The horizontal and vertical axes of the graph indicate a pressure (unit: kPa) in the reaction tube 35 and a microwave power (unit: W), respectively. In the graph, the results of evaluation test 1-1 are indicated by square dots, and the results of evaluation test 1-2 are indicated by circular dots. In the square and circular dots, while dots indicate measurement values, and black dots indicate average values calculated from multiple measurement values.

As clear from the graph, the microwave power at which discharge is initiated is lower in evaluation Test 1-2 than in evaluation test 1-1 under each pressure. Therefore, the power required to produce plasma in the activation region 37 can be reduced by providing the above-described electron supply part. As described above, parameters for various conditions, such as a pressure or a gas flow rate for producing plasma in the activation region 37 can be set over a wide range. Further, as shown in the graph, the variation in measurement values is less in evaluation test 1-2 than in evaluation test 1-1. Therefore, it was clear from evaluation test 1 that the stability of the power at which discharge is initiated is also increased by providing the electron supply part.

### Evaluation Test 2—Space Saving

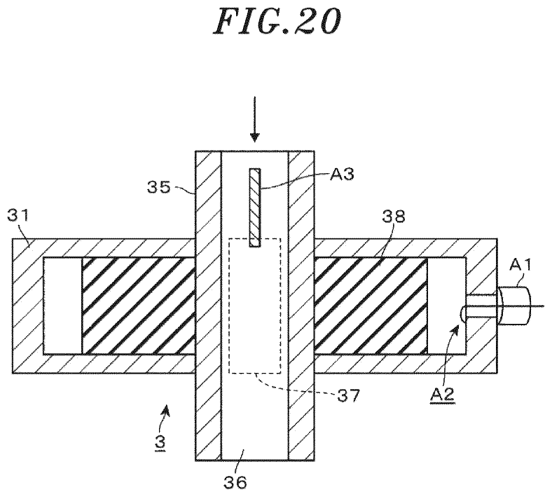

Evaluation test 2 that is another evaluation test related to the present disclosure will be described. An evaluation device used in evaluation test 2 is shown in FIG. 20. In this evaluation device, the resonator 31 is filled with the dielectric 38, i.e., aluminum oxide having a relative dielectric constant of 9, in order to realize scaling down for arranging the microwave reactors 3 in an array. Accordingly, the required inner diameter of the resonator 31 was 91 mm in the device used in evaluation test 1, and was 45 mm in the evaluation device used in evaluation test 2, so that the scaling down of the microwave reactor 3 was achieved. Further, in this evaluation device, a ceramic rod A3 was inserted into the reaction tube 35 instead of using the preliminary discharge plasma P5 to facilitate plasma production. The rod A3 was disposed on the upstream side of the region surrounded by the dielectric 38 in the gas channel 36, and the lower end of the rod A3 was disposed to enter the activation region 37 without entering the region surrounded by the dielectric 38. Due to the distortion of the electric field distribution at the lower end surface of the relatively thin ceramic rod A3, a partial strong electric field portion is formed and, thus, plasma production becomes easier. Further, the microwave power was supplied by a loop antenna A2 installed in the resonator 31 via a coaxial cable A1.

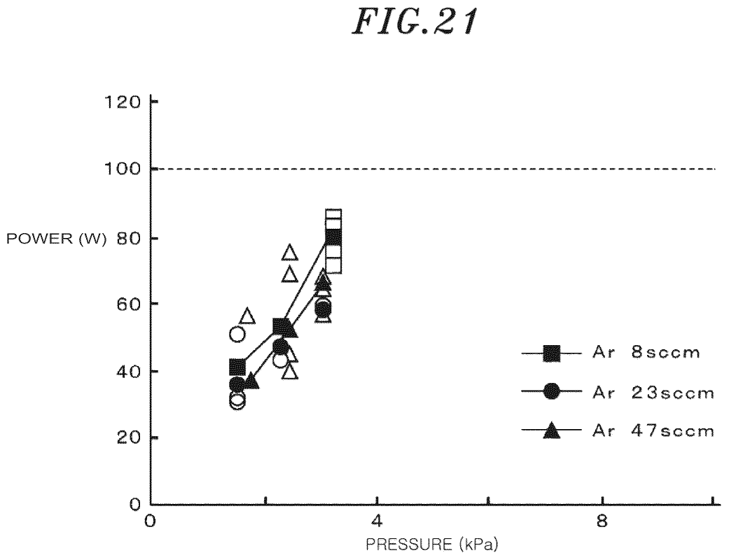

FIG. 21 is a graph plotting the microwave power (power supplied to resonator 31) required to initiate discharge in the case of supplying Ar gas from the top at 8 sccm, 23 sccm, and 47 sccm while reducing the pressure in the reaction tube 35 with a vacuum pump. In the graph, the results for the Ar gas supply amounts of 8 sccm, 23 sccm, and 47 sccm are indicated by square dots, circular dots, and triangular dots, respectively. In addition, white dots indicate measurement values, and black dots indicate average values calculated from multiple measurement values. The frequency of microwaves to be supplied was 2.47 GHz, which is the resonant frequency at which a standing wave of the TM010 mode can be formed in the resonator 31. As shown in the graph, in the evaluation test 2, plasma can be produced in the activation region 37 within a range of 0.8 Pa to 3.5 Pa under microwave irradiation conditions of up to 100 W (indicated by the dotted line in the graph). Plasma can be produced over a wider range by changing the microwave power or the flow rate of the gas to be supplied, and by using preliminary discharge plasma as well. In addition, the same tendency for plasma production was confirmed when the gas to be supplied was helium, nitrogen, or oxygen, and the gas to be supplied can be selected depending on chemical reaction species to be generated in the activation region 37.

When a ceramic with a relative dielectric constant of 40 was used as the dielectric 38, it was possible to set the inner diameter of the resonator 31 to 22 mm. When the resonators 31 were arranged side by side, it was possible to set the gap between the reaction tubes 35 to 25 mm.

### Evaluation Test 3—Installation at Film Forming Apparatus

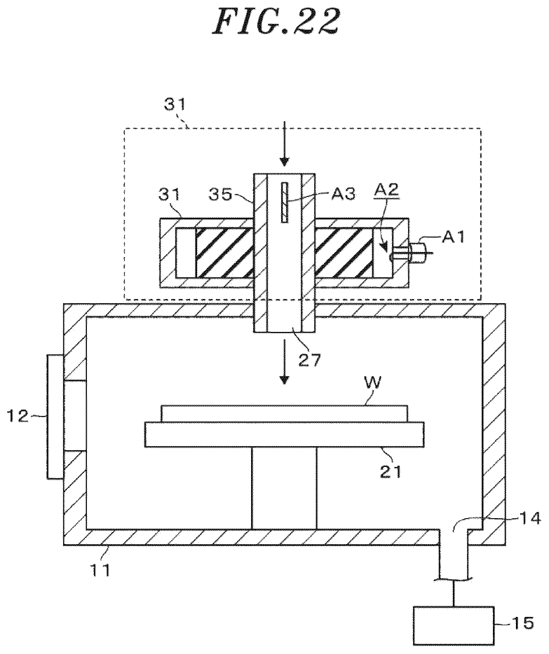

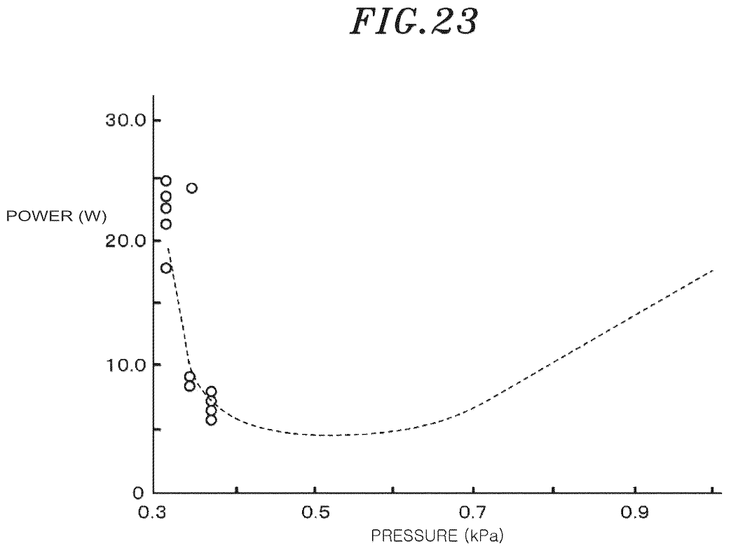

An evaluation test 3, which was performed by installing the microwave reactor 3 at the film forming apparatus, will be described. In the microwave reactor 3, the resonator 31 having an inner diameter of 91 mm and a height of 10 mm was used. In the evaluation test 3, as shown in FIG. 22, the microwave reactor 3 was attached to the upper portion of the processing chamber 11, and the plasma gas ejected from the reaction tube 35 made of quartz and having an inner diameter of 8 mm was sprayed onto the wafer W. The exhaust port 14 disposed at the processing chamber 11 was connected to the exhaust mechanism 15 including a valve, a turbo molecular pump, and a rotary pump. After the pressure in the processing chamber 11 is maintained at a vacuum degree of 10-2 Pa, Ar gas was supplied from the upper side of the reaction tube 35 at 7 sccm to 47 sccm, and the pressure in the reaction tube 35 was controllable within a range of 0.31 kPa to 0.37 kPa. In this state, a microwave of 2.49 GHz, which corresponds to the resonance frequency of the TM010 mode, was supplied from the coaxial cable A1, thereby producing plasma in the reaction tube 35. During plasma production, ionized Ar atoms were ejected from the discharge holes 27 and reached the surface of the wafer W. FIG. 23 shows a plot of the microwave power required to produce plasma with respect to the pressure in the reaction tube 35. In the range of the test, the required microwave power decreases as the pressure increases. If the pressure in the reaction tube 35 is increased by increasing the supply amount of Ar gas, the discharge start power starts to increase as shown in FIG. 19.

1. A substrate processing apparatus comprising:
a processing chamber configured to accommodate a substrate for semiconductor manufacturing or a substrate for flat panel display manufacturing;
a stage disposed in the processing chamber and on which the substrate is placed;
a fluid supply source configured to supply processing fluid to the processing chamber to process the substrate;
a plurality of cylindrical metallic resonators having a bottom portion and a lid, which are disposed in the processing chamber;
a tube body made of a dielectric material, which extends along a central axis of each of the plurality of cylindrical metallic resonators, penetrates the plurality of cylindrical metallic resonators, and forms a fluid channel through which the processing fluid is supplied;
a plurality of discharge holes provided in the processing chamber, each opening toward different positions of the substrate and connected to different fluid channels; and
a plurality of microwave supply sources configured to supply microwaves to different cylindrical metallic resonators from the plurality of cylindrical metallic resonators and activate the processing fluid within an activation region surrounded by the cylindrical metallic resonator in each fluid channel.

2. The substrate processing apparatus of claim 1, wherein the plurality of cylindrical metallic resonators and the plurality of microwave supply sources are provided at a ceiling portion of the processing chamber.

3. The substrate processing apparatus of claim 1, wherein the plurality of microwave supply sources are provided for each of the plurality of cylindrical metallic resonators.

4. The substrate processing apparatus of claim 1, wherein a diffusion space common to each of the fluid channels is provided on an upstream side of each fluid channel in the processing chamber, and the processing fluid is supplied from the fluid supply source into the diffusion space.

5. The substrate processing apparatus of claim 1, wherein the processing fluid is turned into plasma in the activation region by the microwaves, and
an electrode, to which a DC voltage is applied, is provided to selectively supply either ions or electrons constituting the plasma of the processing fluid to the substrate.

6. The substrate processing apparatus of claim 5, wherein the electrode is a ring provided to close an upstream end side of the activation region in the tube body, and a hole formed in the ring forms a channel for supplying the processing fluid supplied from the fluid supply source to the activation region in the tube body.

7. The substrate processing apparatus of claim 1, wherein the processing fluid is turned into plasma in the activation region by the microwaves, and
an electron supply part is provided to supply electrons to the activation region to turn the processing fluid into plasma.

8. The substrate processing apparatus of claim 7, wherein the electron supply part includes an electrode configured to generate electric field on an upstream side of the activation region and generate the electrons from the processing fluid, and a high-frequency power supply configured to supply a high-frequency power to the electrode to generate the electric field.

9. The substrate processing apparatus of claim 7, wherein the electron supply part is provided on an inner wall of the tube body that forms the activation region and is composed of a metal part that is heated by the microwaves.

10. The substrate processing apparatus of claim 7, wherein the electron supply part is a photon supply part configured to supply photons to an upstream side of the activation region or to the activation region itself, to generate electrons from the processing fluid.

11. The substrate processing apparatus of claim 1, wherein a plasma producing mechanism configured to produce plasma on the stage is provided separately from a microwave supply source from the plurality of microwave supply sources.

12. A fluid activation apparatus for activating fluid supplied into a processing chamber which is configured to accommodate and process a substrate for semiconductor manufacturing or a substrate for flat panel display manufacturing, comprising:
a fluid supply source configured to supply the fluid;
a plurality of cylindrical metallic resonators having a bottom portion and a lid;
a tube body made of a dielectric material, which extends along a central axis of each of the plurality of cylindrical metallic resonators, penetrates the cylindrical metallic resonator, and forms a fluid channel through which the fluid from the fluid supply source is supplied;
a plurality of discharge holes provided in the processing chamber, each opening toward different positions in the processing chamber and connected to different fluid channels; and
a plurality of microwave supply sources configured to supply microwaves to different resonators and activate the fluid within an activation region surrounded by the cylindrical metallic resonator in each fluid channel.

13. A substrate processing method comprising:
accommodating a substrate for semiconductor manufacturing or a substrate for flat panel display manufacturing in a processing chamber and placing the substrate on a stage provided in the processing chamber;
supplying processing fluid from a fluid supply source to the processing chamber to process the substrate;
supplying the processing fluid to a fluid channel formed as a tube body that is made of a dielectric material, extends along a central axis of a cylindrical metallic resonator provided in plurality within the processing chamber and having a bottom portion and a lid, and penetrates the cylindrical metallic resonator;
discharging the processing fluid to the substrate from a plurality of discharge holes provided in the processing chamber to open toward different positions of the substrate and connected to different fluid channels; and
supplying microwaves to different resonators by a plurality of microwave supply sources configured to activate the processing fluid in an activation region surrounded by the cylindrical metallic resonator in each fluid channel.

14. A fluid activation method for activating fluid supplied into a processing chamber configured to accommodate and process a substrate for semiconductor manufacturing or a substrate for flat panel display manufacturing, comprising:
supplying fluid from a fluid supply source to a fluid channel formed as tube body that is made of a dielectric material, extends along a central axis of a cylindrical metallic resonator provided in plurality within the processing chamber and having a bottom portion and a lid, and penetrates the cylindrical metallic resonator;
discharging the fluid to the substrate from a plurality of discharge holes provided in the processing chamber to open toward different positions in the processing chamber and connected to different fluid channels; and
supplying microwaves to different resonators from a plurality of microwave supply sources configured to activate the fluid in an activation region surrounded by the cylindrical metallic resonator in each fluid channel.
